(19) United States
(12) Patent Application Publication
(10) Pub. No.: US 2009/0315115 A1
(43) Pub. Date: Dec. 24, 2009

(54) Implantation for shallow trench isolation (STI) formation and for stress for transistor performance enhancement

(75) Inventors: Beichao Zhang, Singapore (SG); Johnny Widodo, Singapore (SG); Juan Boon Tan, Singapore (SG); Yong Kong Siew, Singapore (SG); Fan Zhang, Singapore (SG); Haifeng Sheng, Singapore (SG); Wenhe Lin, Singapore (SG); Young Way Teh, Singapore (SG); Jinping Liu, Singapore (SG); Vincent Ho, Singapore (SG); Liang Choo Hsia, Singapore (SG)

Correspondence Address: DOCKET CLERK, P.O. DRAWER 800889, DALLAS, TX, 75380, US

(73) Assignee: Chartered Semiconductor Manufacturing, Ltd., Singapore (SG)

(21) Appl. No.: 12/214,854

(22) Filed: Jun. 23, 2008

(51) Int. Cl. H01L 21/8234; H01L 27/088

(52) U.S. Cl. 257/368; 438/294; 257/E21.616; 257/E27.06

(57) ABSTRACT

A method (and semiconductor device) of fabricating a semiconductor device provides a shallow trench isolation (STI) structure or region by implanting ions in the STI region. After implantation, the region (of substrate material and ions of a different element) is thermally annealed producing a dielectric material operable for isolating two adjacent field-effect transistors (FET). This eliminates the conventional steps of removing substrate material to form the trench and refilling the trench with dielectric material. Implantation of nitrogen ions into an STI region adjacent a p-type FET applies a compressive stress to the transistor channel region to enhance transistor performance. Implantation of oxygen ions into an STI region adjacent an n-type FET applies a tensile stress to the transistor channel region to enhance transistor performance.

### TECHNICAL FIELD

The present disclosure relates generally to devices and methods of fabrication of semiconductor devices, and more particularly to the fabrication of field-effect transistors (FETs) using implantation to form the STI regions and for stress and performance enhancement.

### BACKGROUND

In complementary metal-oxide semiconductor (CMOS) processing, shallow trench isolation (STI) is utilized to separate adjacent n-type and p-type transistors. In conventional STI processing, typically a thin layer of silicon dioxide is grown or deposited on the substrate material followed by formation of a polish or etch stop layer (such as silicon nitride). A mask is selectively formed to isolate the desired STI regions and material (silicon dioxide layer, silicon nitride layer and substrate material) is removed at those locations to form shallow trenches or recesses within the substrate. After the mask is removed, a dielectric layer, such as silicon dioxide, is formed (grown, deposited, or combination thereof) on the substrate and fills the STI recesses. Typically, the excess dielectric layer, is removed and planarized to the silicon nitride layer, and the nitride layer is removed.

As geometries shrink, conventional STI processing faces problems with depositing dielectric material to fill the STI recess. Accordingly, there is a need for a new STI process (and resulting devices) that avoids or reduces the problems associated with conventional STI processes.

In addition, stress memory techniques (SMT) and stress line techniques (SLT) have been widely used in integrated circuit fabrication to enhance transistor performance in sub-deep-micron geometries and technologies. In both SMT and SLT, mechanical stresses are introduced and applied to nFETs and pFETs using dielectric films deposited on the source/drain and/or poly gate regions of the transistors. However, the application of these dielectrics increases fabrication complexity.

Accordingly, there is a need to have an improved fabrication process (and resulting devices) that introduces mechanical stress to enhance transistor performance in a more simplified manner than current approaches.

### SUMMARY

In accordance with one embodiment, there is provided a method of forming a semiconductor device. The method includes providing a substrate comprising a first substrate material, forming a shallow trench isolation (STI) region by implanting ions of a second material into the substrate, annealing the STI region to form therein a dielectric material comprising the first substrate material and the second material, forming a first field-effect transistor (FET) adjacent the STI region, and forming a second FET adjacent the STI region, wherein the STI region isolates the first FET from the second FET.

In accordance with another embodiment, there is provided a semiconductor device having a semiconductor substrate and first and second first field-effect transistors (FET) formed on the substrate. A shallow trench isolation (STI) structure is formed in the substrate and positioned between and isolating the first FET and the second FET, wherein the STI structure comprises silicon and ions of an element.

In yet another embodiment, there is provided a method of forming shallow trench isolation (STI) regions for use in a semiconductor device. A silicon substrate is provided and ions of a first element are selectively implanted into the silicon substrate to form an STI region. The STI region STI is annealed to form therein a compound dielectric material comprising silicon and the first element. First and second field-effect transistors (FETs) are formed adjacent the STI region, with the STI region isolating the first FET from the second.

Other technical features may be readily apparent to one skilled in the art from the following figures, descriptions, and claims.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 is a cross-sectional view illustrating a semiconductor device configuration in accordance with the present disclosure;

FIGS. 2A-2E are cross-sectional views illustrating various steps of a method or process in accordance with the present disclosure; and

FIGS. 3A-3F are cross-sectional views illustrating various steps of a method or process in accordance with the present disclosure.

### DETAILED DESCRIPTION

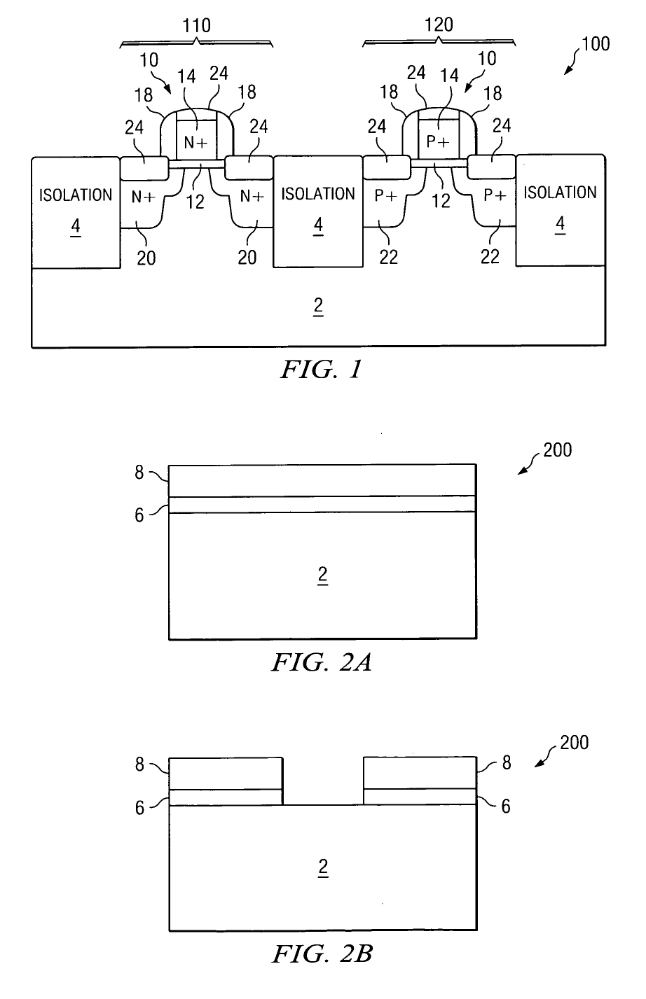

Referring to FIG. 1, there is depicted a cross-sectional view of a semiconductor device structure 100 formed on a substrate 2 in accordance with the present disclosure. The device 100 includes an n-type FET structure 110 and a p-type FET structure 120. The semiconductor device 100 also includes shallow trench isolation (STI) regions 4 for isolating and/or separating the FET structures. Though only the two FET structures 110, 120 and three STI regions 4 are shown, additional p-type or n-type transistors or structures and STI regions 4 may be included therein. As will be appreciated, the STI regions 4 may be utilized to isolate and separate different type FETs as well as same type FETs. Further, the structures and regions shown in the FIGURES are not drawn to scale or actual form, and are for illustrative purposes.

The nFET structure 110 includes a gate stack 10 having a gate dielectric 12, a polysilicon gate 14 and sidewall spacers 18. Two n-type regions 20 form the source/drain (S/D) regions. A silicide layer 24 is formed on the gate 14 and the S/D regions 20, as shown. The PFET structure 120 includes a similar gate stack 10 having a gate dielectric 12, a polysilicon gate 14 and sidewall spacers 18. Two p-type regions 22 form the source/drain (S/D) regions. The silicide layer 24 is formed on the gate 14 and S/D the regions 22, as shown. The nFET and PFET structures 110 and 120 may be formed in accordance with any prior art (or later developed) processes or techniques. In addition, the S/D regions of the p-type FET 120 may include other materials, such as Silicon-Germanium (SiGe).

Substrate 2 may include, for example, silicon, silicon-on-insulator (SOI), or other suitable semiconductor substrate materials, now known or later developed. The substrate 2 may include silicon (e.g., n-type, p-type, or no type) provided in a single well or twin-well process, and may further include an epitaxial layer.

As will be understood, the semiconductor device 100 and the FET structures 110, 120 may be formed using conventional processes, except that the STI regions 4 include a dielectric material formed using an implantation process, as described in detail below. This process eliminates the steps of removing a portion of the substrate material 2 (to form a recess) and refilling the recess with dielectric material. Instead, the present disclosure provides for an implantation process that implants materials within the substrate material to form the dielectric material of the STI region 4.

As will be appreciated, the term “shallow trench isolation” (or the acronym “STI” to which it applies) may imply that a trench is formed by the removal of material. As that term is used herein (without other qualifiers), the term also refers to an isolation region or structure positioned between two FET structures on the substrate for the purposes of separation or isolation, regardless of whether material is physically removed to form a trench or recess (which may be later filled) in accordance with prior art teachings.

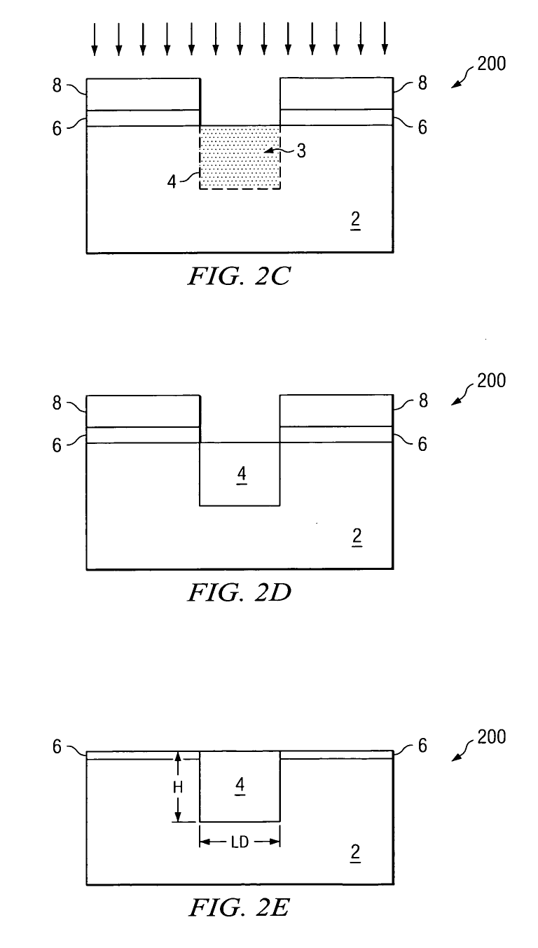

Now referring to FIGS. 2A-2E, there are shown cross-sectional views of a process in accordance with this disclosure. With specific reference to FIG. 2A, there is shown an initial structure 200 including the substrate 2 having one or more layers 6 formed thereon. The layer 6 may include a silicon oxide layer (that forms a gate oxide or other stress relief layer) and a silicon nitride layer. In conventional processing, a silicon nitride etch/polish stop layer is utilized, however, in this process, the silicon nitride layer may be optional.

A next step in the process includes forming a mask layer 8 over the substrate 2. The mask layer 8 may be formed using silicon oxide, silicon nitride, photoresist or combinations thereof. The mask layer 8 may be deposited using low pressure chemical vapor deposition (LPCVD), plasma enhanced chemical vapor deposition (PECVD) or rapid thermal chemical vapor deposition (RTCVD).

Referring to FIG. 2B, a next step in the process includes selectively removing portions of the mask layer 8 via lithography to define the STI regions 4. Any other layers 6 are removed also.

After the lithography/patterning step, implants or ions 3 are implanted into the substrate 2 through the exposed regions to form the STI regions 4, as illustrated in FIG. 2C. The eventual STI regions 4 that will be formed are shown with dashed lines. The implants 3 are shown implanted within the semiconductor substrate 2 within the approximate area illustrated by the dashed lines. Various ion materials may be implanted, including materials that react with the substrate material to form a dielectric or insulative material providing separation and isolation characteristics. In various embodiments, the implants may be oxygen, nitrogen or a combination of oxygen and nitrogen.

During the implantation process, the implanted ions are imparted with different energy levels to produce a relatively uniform dose distribution (depth) into the substrate 2. Implant energy levels may range from a few eV to a few hundred keV, depending on the targeted STI depth to be formed and the implant species. Implant dosage may range from 5×10¹⁶ cm² to 5×10¹⁸ cm², depending on the implant species, as well.

After implantation, the structure 200 undergoes an annealing process. This annealing process may include thermal annealing or some other thermal process, and may include furnace or laser annealing. The annealing temperature may range from a few hundred degrees to 1300 degrees Celsius, depending on the implant species. In addition, the wafer temperature may be raised to between about 400 and 700 degrees Celsius during implantation to form silicon nitride (SiₓN_{y}) or silicon oxide (SiₓO_{y}) instantly or assist a subsequent formation at a relatively lower annealing temperature.

The annealing process combines the substrate material (within the substrate 2) and implants 3 into a dielectric material forming the STI material or region 4. For example, the material of the STI region 4 may include SiₓO_{y} (silicone oxide), SiₓN_{y} (silicon nitride) or SiOₓN_{y} (silicon-oxide-nitride), depending on the implant material. This material, thus, forms the isolation or insulation “trench” (i.e., the STI region 4) within the substrate 2, as shown on FIG. 2D.

Either before or after the annealing process, the mask layer 8 is removed (FIG. 2E illustrates the structure 200 after anneal and mask removal steps). After annealing, the structure undergoes further conventional semiconductor processing to form additional structures, such as transistor structures 110, 120, on the substrate 2 to eventually produce the semiconductor device 100 (as formed as illustrated in FIG. 1.

As shown in FIG. 2E, the STI region 4 with the dielectric material formed as described may be of various geometry. In one embodiment, the STI region 4 has a lateral dimension (LD) at a narrow point and a height (H). Though the STI region 4 may have dimensions typical of conventional state-of-the-art integrated circuits, in one embodiment, the lateral dimension is greater than about 50 nanometers (nm), while the height dimension may be between about 100 nm and about 500 nm. In this embodiment, the aspect ratio (height divided by width) of the STI region (at a particular narrow point location) may be between about 1:1 to 10:1. In another embodiment, the minimum lateral dimension may be less than about 70 nm, while the height may be relatively small and range up to about 600 nm (or up to about 400 or about 500 nm), thus providing an aspect ratio of greater than about 8:1. In another embodiment, and described in another way, the aspect ratio of the STI region 4 at a particular location may be about 8:1 or greater, and in another embodiment, may be about 10:1 or greater. As noted above, when geometries shrink, conventional STI processing faces problems with depositing dielectric material to fill a conventional STI recess. The present disclosure reduces this problem by allowing an increase in the aspect ratio (reducing the lateral dimension LD, increasing the height H, or both) of the STI region 4 as compared to conventionally formed STI regions, thus allowing smaller STI regions. Though various dimensions and aspect ratios are described, the process and structure of the present disclosure may also be used with larger dimensions and smaller aspect ratios.

It will be understood that the foregoing process is not limited to formation of dielectric regions 4 functioning as traditional STI regions between transistors of different types. The regions 4 may also be formed between transistors of the same type to reduce or eliminate inter-transistor leakage (as will be described below).

As described previously, strain engineering techniques are used in semiconductor manufacturing. Prior art approaches focus on applying tensile or compressive stress on the transistor channel to enhance performance. PFET performance is enhanced by compressive stress while nFET performance is enhanced from tensile stress. These approaches induce strain locally, allowing both n-channel and p-channel stress to be produced independently.

In one approach, a strain-inducing capping layer of silicon nitride is selectively deposited on the pFET or nFET structure. Silicon nitride may be used to create the desired stress for either type of structure depending on the deposition conditions. Conventional patterning and lithography techniques are used to selectively deposit a tensile silicon nitride film over the nFET structure and a compressive silicon nitride film over the PFET.

In another approach, a silicon composition, such as silicon-germanium (SiGe), is used assist in generating the channel stress. Typically, silicon is epitaxially grown on top of a relaxed silicon-germanium underlayer. Strain is induced in the silicon as the lattice of the silicon layer is stretched to mimic the larger lattice constant of the underlying SiGe layer resulting in a compressive strain on the channel (for PFET structures). For nFET structures, tensile stress may be induced by using a smaller lattice constant, such as silicon-carbon.

It has been determined that the process and structures as described herein may also introduce mechanical stresses to nFET and/or pFET transistor channels.

In general terms, the present disclosure provides a process (and resulting structure) in which ions are implanted in STI regions surrounding transistors to provide a tensile or compressive film that results in the application of compressive or tensile stress to enhance transistor performance.

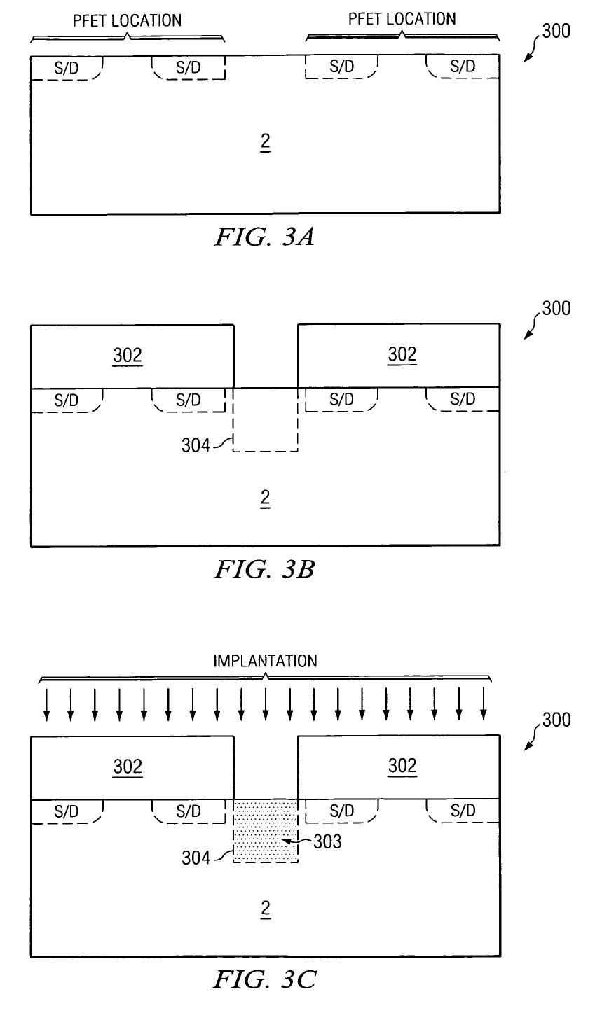

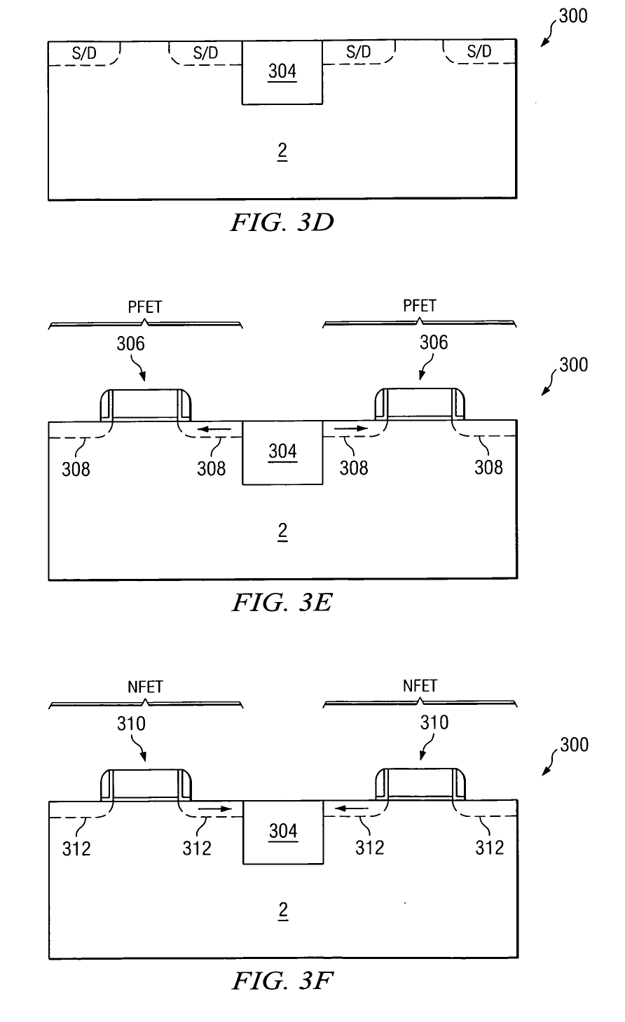

Now referring to FIGS. 3A-3D, there are shown cross-sectional views of a process in accordance with this disclosure. With specific reference to FIG. 3A, there is shown an initial structure 300 including the substrate 2. Dashed lines illustrate source/drain regions of two contemplated PFET structures that will be subsequently formed on the substrate 2. As will be appreciated, when the substrate 2 is n-type when pFETs are fabricated.

A next step in the process includes forming a mask layer 302 over the substrate 2. The mask layer 302 may be formed using silicon oxide, silicon nitride, photoresist or combinations thereof. The mask layer 302 may be deposited using low pressure chemical vapor deposition (LPCVD), plasma enhanced chemical vapor deposition (PECVD) or rapid thermal chemical vapor deposition (RTCVD).

Though no additional layers are illustrated between the substrate 2 and the mask layer 302, one or more layers may be formed therebetween. Depending on the process, such layer(s) might a silicon oxide layer (that forms a gate oxide or other stress relief layer) and/or a silicon nitride layer.

Referring to FIG. 3B, a next step in the process includes selectively removing portions of the mask layer 302 via lithography to define a stress inducing region 304. This stress inducing region 304 may be considered equivalent or similar to the STI regions 4 (as described above in FIGS. 1 and 2A-2E). The stress inducing region 304 isolates, separates and/or is positioned laterally adjacent to the two contemplated FET structures. Though only two FET structures and one STI region 4 are shown, additional p-type or n-type transistors and/or STI regions 4 may be included therein.

After the lithography/patterning step, nitrogen implants or ions 303 are implanted into the substrate 2 through the exposed region to form the stress inducing region 304 (the eventually formed region is shown with dashed lines), as illustrated in FIG. 3C. The implants 303 are shown implanted within the semiconductor substrate 2 within the approximate area illustrated by the dashed lines of region 304. Various implants or ion materials may be implanted, including materials that react with the substrate material to form a dielectric or insulative material providing not only separation and isolation characteristics, but also form a tensile film with tensile stress (laterally outward stress). Materials other than nitrogen ions may be implanted to form the tensile film within the region 304, and thus silicon nitride is but one material that may be sued to form the tensile film.

During the implantation process, the implanted ions are imparted with different energy levels to produce a relatively uniform dose distribution (depth) into the substrate 2. Implant energy levels may range from a few eV to a few hundred keV, depending on the targeted STI depth to be formed and the implant species. Implant dosage may range from 5×10¹⁶ cm² to 5×10¹⁸ cm², depending on the implant species, as well.

After implantation, the structure 300 undergoes an annealing process, as shown in FIG. 3D. This annealing process may include thermal annealing or some other thermal process, and may include furnace or laser annealing. The annealing temperature may range from a few hundred degrees to 1300 degrees Celsius, depending on the implant species. In addition, the wafer temperature may be raised to between about 400 and 700 degrees Celsius during implantation to form silicon nitride (SiₓN_{y}) instantly or assist a subsequent formation at a relatively lower annealing temperature.

The annealing process combines the substrate material (within the substrate 2) and implants into a dielectric material SiₓN_{y} (silicon nitride) forming the stress inducing region 304 having tensile stress. This material, thus, forms the stress inducing region 304, which may also be referred to as an STI region, within the substrate 2.

Either before or after the annealing process, the mask layer 302 is removed (FIG. 3D illustrates the structure after anneal and mask removal steps). After the annealing process, the structure undergoes further conventional semiconductor processing to form additional structures, such as pFET gates 306 and S/D regions 308 formation, that eventually produces the semiconductor device 100 as illustrated in FIG. 1, but wherein the two transistors 110, 120 are both p-type and the STI region 4 is a stress inducing region 304. As shown in FIG. 3E, the stress inducing region 304 imposes a compressive stress (in the direction of the illustrated arrows) on the channels of the two adjacent pFETs.

Though only two pFET structures are shown, additional p-type transistors and stress inducing regions 304 may be included therein.

As will be appreciated, FIGS. 3A-3E illustrate the introduction of a compressive stress on the channel of pFETs using an implanted isolation structure 304. Similar processing steps can be used to introduce a tensile stress on the channel of nFETs using an implanted isolation structure. For brevity, only one additional FIG. 3F (similar to FIG. 3E) is provided to illustrate the concept and resulting structure for nFETs (nFET gates 310 and S/D regions 312), however, the differences from the process illustrated in FIGS. 3A-3E are also described below.

For construction of nFETs, the substrate 2 is p-type. Instead of implanting nitrogen into the substrate 2, the stress inducing regions are formed with various ion materials, such as oxygen, that react with the substrate material to form a dielectric or insulative material providing not only separation and isolation characteristics, but also form a compressive film with compressive stress (laterally inward stress).). Materials other than oxygen ions may be implanted to form the compressive film within the region, and thus silicon oxide is but one material that may be used to form a compressive film.

The annealing process combines the substrate material (within the substrate 2) and implants into a dielectric material SiₓO_{y} (silicon oxide) forming the stress inducing region 304 having compressive stress. As shown in FIG. 3F, the stress inducing region 304 imposes a tensile stress (as shown using arrows) on the channels of the two adjacent pFETs.

In the different embodiments described, the implanted material 3, 303 (e.g. ions) are implanted below the surface of the substrate 2, or are otherwise buried in the substrate material 2. In other words, ions 3, 303 of an element (e.g., nitrogen, oxygen) are buried or implanted within the material of the substrate 2. Thus, after implantation, the regions 4, 304 include both substrate material (e.g., silicon) and ions of an element (different from the substrate material). The ions are suspended or interspersed within the substrate material. The annealing process causes interaction (reaction) between the ions and the substrate material resulting in the formation of a dielectric compound (e.g., silicon nitride, silicon oxide).

The order of steps or processing can be changed or varied form that described above. It will be understood well known process have not been described in detail and have been omitted for brevity. Although specific steps, insulating materials, conductive materials and apparatuses for depositing and etching these materials may have been described, the present disclosure may not limited to these specifics, and others may substituted as is well understood by those skilled in the art.

It may be advantageous to set forth definitions of certain words and phrases used throughout this patent document. The terms “include” and “comprise,” as well as derivatives thereof, mean inclusion without limitation. The term “or” is inclusive, meaning and/or. The phrases “associated with” and “associated therewith,” as well as derivatives thereof, mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of forming a semiconductor device, the method comprising:
providing a substrate comprising a first substrate material;
forming a shallow trench isolation (STI) region by implanting ions of a second material into the substrate;
annealing the STI region to form therein a dielectric material comprising the first substrate material and the second material;
forming a first field-effect transistor (FET) adjacent the STI region; and
forming a second FET adjacent the STI region, wherein the STI region isolates the first FET from the second FET.

2. The method in accordance with claim 1 wherein the first substrate material comprises silicon and the second material comprises a one of: nitrogen, oxygen, and a combination of nitrogen and oxygen.

3. The method in accordance with claim 1 wherein annealing the STI region includes thermal annealing.

4. The method in accordance with claim 1 wherein the first FET comprises a p-type FET having a channel and two source/drain regions, and the method further comprises:
applying a compressive stress to the channel of the first FET.

5. The method in accordance with claim 4 wherein applying the compressive stress is generated by the dielectric material within the STI region.

6. The method in accordance with claim 5 wherein the first substrate material comprises silicon and the second material includes nitrogen.

7. The method in accordance with claim 1 wherein the first FET comprises an n-type FET having a channel and two source/drain regions, and the method further comprises:
applying a tensile stress to the channel of the first FET.

8. The method in accordance with claim 7 wherein applying the tensile stress is generated by the dielectric material within the STI region.

9. The method in accordance with claim 8 wherein the first substrate material comprises silicon and the second material includes oxygen.

10. The method in accordance with claim 1 wherein the ions implanted into the substrate are implanted with differing energy levels to provide a substantially uniform distribution depthwise within the STI region.

11. A semiconductor device comprising:
a semiconductor substrate;
a first field-effect transistor (FET) formed on the substrate;
a second FET formed on the substrate;
a shallow trench isolation (STI) structure formed in the substrate and positioned between and isolating the first FET and the second FET, wherein the STI structure comprises silicon and ions of an element.

12. The device in accordance with claim 11 wherein the ions are implanted beneath a surface of the substrate and the silicon and ions are thermally annealed to form a dielectric compound.

13. The device in accordance with claim 12 wherein the dielectric compound comprises a one of: SiₓO_{y}, SiₓN_{y} or SiOₓN_{y}.

14. The device in accordance with claim 14 wherein first FET includes p-type FET having a channel and two source/drain regions and the STI region applies a compressive stress to at least a portion of the channel.

15. A method of forming shallow trench isolation (STI) regions for use in a semiconductor device, the method comprising:
providing a silicon substrate;
selectively implanting ions of a first element into the silicon substrate to form an STI region;
annealing the STI region to form therein a compound dielectric material comprising silicon and the first element;
forming a first field-effect transistor (FET) adjacent the STI region; and
forming a second FET adjacent the STI region, the STI region isolating the first FET from the second FET.

16. The method in accordance with claim 15 wherein the compound dielectric material comprises a one of: SiₓO_{y}, SiₓN_{y} or SiOₓN_{y}.

17. The method in accordance with claim 16 wherein annealing the STI region includes thermal annealing.

18. The method in accordance with claim 15 wherein the ions implanted into the substrate are implanted with differing energy levels to provide a substantially uniform distribution depthwise within the STI region.

19. The method in accordance with claim 15 further comprising:
applying a one of a tensile stress and a compressive stress to a channel region of the first FET.

20. The method in accordance with claim 19 wherein the first FET and the second FET are both of a first type.
